(19) United States
(12) Patent Application Publication
(10) Pub. No.: US 2008/0045025 A1
(43) Pub. Date: Feb. 21, 2008

(54) SEMICONDUCTOR DEVICE MANUFACTURING METHOD

(75) Inventors: Ryuichi ASAKO, Nirasaki-shi (JP); Yuki CHIBA, Nirasaki-shi (JP); Kazuhiro KUBOTA, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/840,767

(22) Filed: Aug. 17, 2007

(30) Foreign Application Priority Data
Aug. 18, 2006 (JP) 2006-223530

(51) Int. Cl. H01L 21/302

(52) U.S. Cl. 438/706; 257/E21.214

(57) ABSTRACT

A method includes forming an etching mask having a predetermined circuit pattern on an Si-containing low dielectric constant film disposed on a semiconductor substrate; performing etching on the Si-containing low dielectric constant film through the etching mask by use of an F-containing gas, thereby forming a groove or hole; performing ashing by use of NH₃ gas after said etching, thereby removing the etching mask; removing a by-product generated during said ashing; and then supplying a predetermined recovery gas, thereby recovering damage of the Si-containing low dielectric constant film caused before or in said removing the etching mask.

### BACKGROUND OF THE INVENTION

1. Field of the Invention

The present invention relates to a method of manufacturing a semiconductor device by use of, e.g., a single damascene method or dual damascene method.

2. Description of the Related Art

In semiconductor device manufacturing processes, a dual damascene method is frequently used for forming interconnection lines embedded in grooves and/or connection holes (for example, see U.S. patent application Ser. No. 10/380,038). FIGS. 1A to 1I are explanatory views schematically showing a method of forming a Cu interconnection line, using a conventional dual damascene method.

At first, for example, an interconnection layer 500, an inter-level insulating film 501, and an anti-reflective coating 502 are formed in this order on a substrate. Further, a first resist film 503 is formed on the surface of the multi-layer structure thus formed (FIG. 1A). Then, patterning of the first resist film 503 is performed by a photolithography technique to form a predetermined pattern (FIG. 1B). In this patterning step, the first resist film 503 is subjected to light exposure with a predetermined pattern, and the light-exposed portion is selectively removed by development. Subsequently, the anti-reflective coating 502 and inter-level insulating film 501 are etched by an etching process using the first resist film 503 as a mask. Consequently, a connection hole 504 is formed to extend from the surface of the multi-layer structure to the interconnection layer 500 (FIG. 1C).

Thereafter, for example, the first resist film 503, which is not necessary any more, is peeled and removed by an ashing process (FIG. 1D). Then, a new second resist film 505 for forming an interconnection groove is formed (FIG. 1E). Then, patterning of the second resist film 505 is performed by a photolithography technique (FIG. 1F). Then, the anti-reflective coating 502 and a part of the inter-level insulating film 501 are etched by an etching process using the second resist film 505 as a mask. Consequently, an interconnection groove 506 is formed to be connected to the connection hole 504 and wider than the connection hole 504 (FIG. 1G). Then, the second resist film 505, which is not necessary any more, is peeled and removed (FIG. 1H). Then, the connection hole 504 and interconnection groove 506 are filled with Cu material, so that a Cu interconnection line 507 is formed (FIG. 1I).

Incidentally, with a decrease in size of semiconductor devices, the parasitic capacitance of inter-level insulating films has become an important factor to improve the performance of interconnection lines. For this purpose, low dielectric constant materials (Low-k materials) are used as the material of inter-level insulating films. In general, materials including alkyl groups, such as methyl groups, as end groups are used as low dielectric constant materials (Low-k materials) for forming inter-level insulating films.

However, according to the conventional damascene process described above, when etching or resist film removal is performed, the inter-level insulating film 501 made of a Low-k material is damaged. This damage increases the dielectric constant of the inter-level insulating film 501, and deteriorates some effects obtained by using the Low-k material.

As a technique for recovering such damage, U.S. patent application Ser. No. 11/631,387 discloses a method for performing a silylation process after etching or resist film removal. This silylation process is arranged to reform damaged surface portions by a silylation agent, thereby forming end groups of alkyl groups, such as methyl groups.

As an inter-level insulating film made of a Low-k material (Low-k film), a film with a skeleton containing Si is frequently used. In general, where an Si-containing Low-k film of this type is etched, an F-containing gas, such as CF₄ gas, is used. In this case, if an NH₃-based gas is used thereafter to remove a resist film used as an etching mask, a new problem arises in that a subsequent silylation process cannot work well to recover damage. Even if a gas other than an NH₃-based gas is used for ashing, this problem also arises in a case where an F-containing gas is used to etch an Si-containing Low-k film and an NH₃-based gas is then brought into contact with etched portions.

### BRIEF SUMMARY OF THE INVENTION

An object of the present invention is to provide a semiconductor device manufacturing method that can recover damage of an etched portion of an Si-containing low dielectric constant film treated as an etching target film, even if the etched portion is exposed to an NH₃-based gas after the Si-containing low dielectric constant film is etched by an F-containing gas and when or before an etching mask is removed.

Another object of the present invention is to provide a storage medium that stores a program for a computer to execute this method.

According to a first aspect of the present invention, there is provided a semiconductor device manufacturing method comprising: forming an etching mask having a predetermined circuit pattern on an Si-containing low dielectric constant film disposed as an etching target film on a semiconductor substrate; performing etching on the Si-containing low dielectric constant film through the etching mask by use of an F-containing gas, thereby forming a groove or hole in the Si-containing low dielectric constant film; performing ashing after said etching, thereby removing the etching mask; bringing about a state where an etched portion of the Si-containing low dielectric constant film is exposed to NH₃ gas after said etching and before or in said removing the etching mask; removing a by-product formed on the etched portion of the Si-containing low dielectric constant film due to exposure to the NH₃ gas; and supplying a predetermined recovery gas after said removing a by-product, thereby recovering damage of the Si-containing low dielectric constant film caused before or in said removing the etching mask.

According to a second aspect of the present invention, there is provided a storage medium that stores a program for execution on a computer to control a manufacturing system, wherein the program, when executed, causes the computer to control the manufacturing system to conduct a semiconductor device manufacturing method comprising: forming an etching mask having a predetermined circuit pattern on an Si-containing low dielectric constant film disposed as an etching target film on a semiconductor substrate; performing etching on the Si-containing low dielectric constant film through the etching mask by use of an F-containing gas, thereby forming a groove or hole in the Si-containing low dielectric constant film; performing ashing after said etching, thereby removing the etching mask; bringing about a state where an etched portion of the Si-containing low dielectric constant film is exposed to NH₃ gas after said etching and before or in said removing the etching mask; removing a by-product formed on the etched portion of the Si-containing low dielectric constant film due to exposure to the NH₃ gas; and supplying a predetermined recovery gas after said removing a by-product, thereby recovering damage of the Si-containing low dielectric constant film caused before or in said removing the etching mask.

Where an Si-containing low dielectric constant film disposed as an etching target film is etched by use of an F-containing gas, and then the etched portion of the Si-containing low dielectric constant film is exposed to an NH₃-based gas for, e.g., ashing, a subsequent recovering process cannot work well to recover damage. The present inventors studied the causes of this problem and have found that Si contained in the Si-containing low dielectric constant film, F contained in the etching gas remaining on the etched portion, and the NH₃-based gas react with each other, and a silicon fluoride ammonium family substance is thereby generated on the etched portion. If a recovery gas, such as a silylation agent, is caused to react under this condition, the recovery gas may react with moisture contained in the silicon fluoride ammonium family substance before it reacts with the damage portion of the film, thereby hindering the recovering process for recovering damage. Based on the findings given above, the present inventors have further found that removal of the by-product prior to the recovering process allows the recovering process to reliably provide its effect, and thus arrived at the arrangement described above.

In the first aspect described above, said removing the etching mask may be performed by ashing by use of a gas containing NH₃ gas, which brings about the state where an etched portion of the Si-containing low dielectric constant film is exposed to NH₃ gas. Said removing a by-product may be performed by a plasma process. In this case, the plasma process may be performed while turning Ar gas, H₂ gas, or He gas into plasma in a vacuum. Where a plasma process is used for said removing a by-product, said removing a by-product and said removing the etching mask may be performed within the same process chamber, or said removing a by-product, said removing the etching mask, and said recovering damage may be performed within the same process chamber.

Said removing a by-product may be performed by a heat process. In this case, the heat process is preferably performed at a temperature of 150 to 350° C.

Where a plasma process or heat process is used for said removing a by-product, said etching, said removing a by-product, said removing the etching mask, and said recovering damage may be performed by a process system of a cluster type that comprises a plurality of process chambers each configured to perform a process within a vacuum atmosphere, and a transfer mechanism configured to transfer a semiconductor substrate between the process chambers without breaking a vacuum.

In the present invention, said removing a by-product may be performed by cleaning by use of a cleaning liquid.

Said recovering damage may be performed by a silylation process by use of a silylation gas as the recovery gas. In this case, the silylation process may be performed by use of a compound including silazane bonds (Si—N) in molecules as the recovery gas. The compound including silazane bonds in molecules may be selected from TMDS (1,1,3,3-Tetramethyldisilazane), TMSDMA (Dimethylaminotrimethylsilane), DMSDMA (Dimethylsilyldimethylamine), TMSPyrole (1-Trimethylsilylpyrole), BSTFA (N,O-Bis(trimethylsilyl)trifluoroacetamide), and BDMADMS (Bis(dimethylamino)dimethylsilane).

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIGS. 1A to 1I are sectional views showing steps of a semiconductor device manufacturing process using a conventional dual damascene method;

FIG. 2 is an explanatory view schematically showing the arrangement of a semiconductor device manufacturing system used for a semiconductor device manufacturing process according to an embodiment of the present invention;

FIG. 3 is a plan view schematically showing the structure of an etching/ashing/by-product-removing/recovering system used in the semiconductor device manufacturing system shown in FIG. 2;

FIG. 4 is a sectional view schematically showing an etching unit disposed in the etching/ashing/by-product-removing/recovering system;

FIG. 5 is a sectional view schematically showing an ashing unit disposed in the etching/ashing/by-product-removing/recovering system;

FIG. 6 is a sectional view schematically showing a by-product-removing unit disposed in the etching/ashing/by-product-removing/recovering system;

FIG. 7 is a sectional view schematically showing a silylation unit disposed in the etching/ashing/by-product-removing/recovering system;

FIG. 8 is a flowchart showing a semiconductor device manufacturing process employing a single damascene method, performed by the semiconductor device manufacturing system shown in FIG. 2;

FIGS. 9A to 9H are sectional views showing steps of the flow shown in FIG. 8;

FIG. 10 is a flowchart showing a semiconductor device manufacturing process employing a dual damascene method, performed by the semiconductor device manufacturing system shown in FIG. 2;

FIGS. 11A to 11K are sectional views showing steps of the flow shown in FIG. 10;

FIG. 12 is a sectional view showing a baking unit used for a by-product-removing process; and

FIG. 13 is a sectional view showing a cleaning unit used for a by-product-removing process.

### DETAILED DESCRIPTION OF THE INVENTION

An embodiment of the present invention will now be described with reference to the accompanying drawings. Hereinafter, the present invention is exemplified by a case where a semiconductor device is manufactured by a single damascene method and a case where a semiconductor device is manufactured by a dual damascene method.

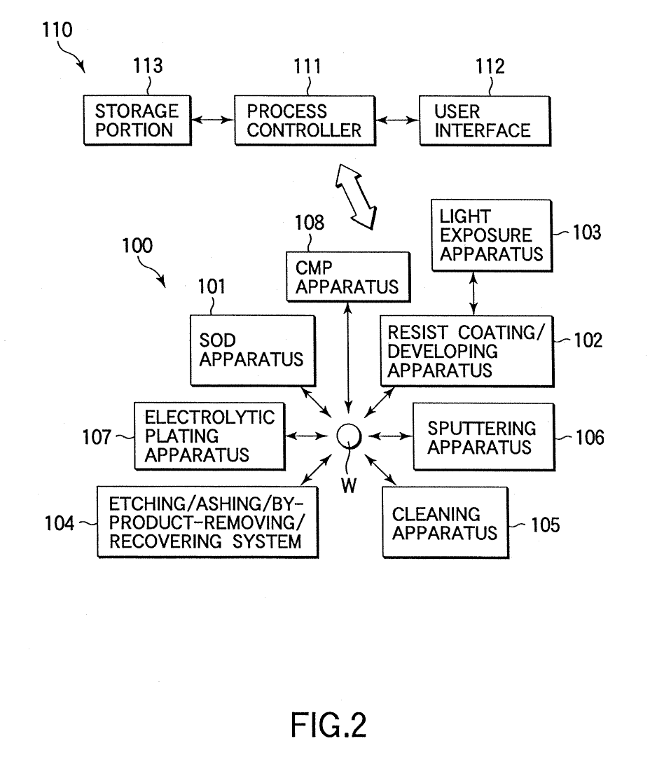

FIG. 2 is an explanatory view schematically showing the arrangement of a semiconductor device manufacturing system used for a semiconductor device manufacturing process according to an embodiment of the present invention. This semiconductor device manufacturing system includes a process section 100 and a main control section 110 for controlling the respective components of the process section 100. The process section 100 includes an SOD (Spin On Dielectric) apparatus 101, a resist coating/developing apparatus 102, a light exposure apparatus 103, an etching/ashing/by-product-removing/recovering system 104 for performing dry etching, dry ashing, by-product-removing, and recovering processes, a cleaning apparatus 105, a sputtering apparatus 106 used as a PVD apparatus, an electrolytic plating apparatus 107, and a CMP apparatus 108 used as a polishing apparatus. The main control section 110 includes a process controller 111, a user interface 112, and a storage portion 113. The SOD apparatus 101, sputtering apparatus 106, and electrolytic plating apparatus 107 of the process section 100 are film formation apparatuses. As a method for transferring a wafer W between apparatuses in the process section 100, a transfer method by an operator and/or a transfer method by a transfer unit (not shown) are used.

The process controller 111 of the main control section 110 comprises a micro-processor (computer), and the respective components in the process section 100 are connected to and controlled by the process controller 111. The process controller 111 is connected to the user interface 112 and storage portion 113. The user interface 112 includes a keyboard and a display, wherein the keyboard is used for an operator to input commands for operating the apparatuses in the process section 100, and the display is used for showing visualized images of the operational status of the apparatuses in the process section 100. The storage portion 113 stores recipes with control programs and process condition data recorded therein for realizing various processes performed in the process section 100 under the control of the process controller 111. A required recipe is retrieved from the storage portion 113 and executed by the process controller 111 in accordance with an instruction or the like input through the user interface 112. Consequently, each of various predetermined processes is performed in the process section 100 under the control of the process controller 111. Recipes may be stored in a readable storage medium, such as a CD-ROM, hard disk, flexible disk, or nonvolatile memory. Further, recipes may be utilized on-line, while it is transmitted among the respective apparatuses in the process section 100, or transmitted from an external apparatus through, e.g., a dedicated line, as needed.

The main control section 110 may be arranged to control all the apparatuses, or may be arranged to perform only global control, while each of the apparatuses or each predetermined set of apparatuses is provided with and controlled by its own subordinate control section.

The SOD apparatus 101 is used to apply a chemical solution onto a wafer W to form an inter-level insulating film formed of an Si-containing Low-k film, or an etching stopper film, by a spin coating method. Although the structure of the SOD apparatus 101 is not shown in detail, the SOD apparatus 101 includes a spin coater unit and a heat processing unit to perform a heat process on a wafer W with a coating film formed thereon. In the case of a wafer processing system, a CVD apparatus may be used to form an insulating film on a wafer W by a chemical vapor deposition (CVD) method, in place of the SOD apparatus 101.

The resist coating/developing apparatus 102 is used to form a resist film used as an etching mask, and an anti-reflective coating. Although the resist coating/developing apparatus 102 is not shown in detail, the resist coating/developing apparatus 102 includes a resist coating unit, a BARC coating unit, a sacrificial film coating unit, a developing unit, and thermal processing units. The resist coating unit is arranged to apply a resist liquid onto a wafer W to form a resist film by spin coating. The BARC coating unit is arranged to apply an anti-reflective coating (BARC) onto a wafer W. The sacrificial film coating unit is arranged to apply a sacrificial film onto a wafer W. The developing unit is arranged to perform a development process on a resist film which has been subjected to light exposure with a predetermined pattern in the light exposure apparatus 103. The thermal processing units are arranged to respectively perform thermal processes on a wafer W with a resist film formed thereon, a wafer W treated by a light exposure process, and a wafer W treated by a development process. The light exposure apparatus 103 is used to subject a wafer W with a resist film formed thereon to light exposure with a predetermined circuit pattern.

As described later in detail, the etching/ashing/by-product-removing/recovering system 104 is arranged to perform a dry etching process to form via-holes or trenches in a predetermined pattern in an inter-level insulating film (Low-k film), a dry ashing process to remove a resist film, and a recovering process for recovering damage of an inter-level insulating film. These processes are sequentially performed as dry processes in a vacuum.

The cleaning apparatus 105 is used to perform a cleaning process on a wafer W by use of a process liquid, and includes a cleaning unit described later, a heating unit for drying a wafer W by heating after cleaning, and a transfer mechanism for transferring a wafer W between units.

The sputtering apparatus 106 is used to form, e.g., each of an anti-diffusion film and a Cu seed layer. The electrolytic plating apparatus 107 is arranged to embed Cu in an interconnection groove and so forth having a Cu seed layer formed therein. The CMP apparatus 108 is arranged to perform a planarization process on a surface of an interconnection line filled with Cu and so forth.

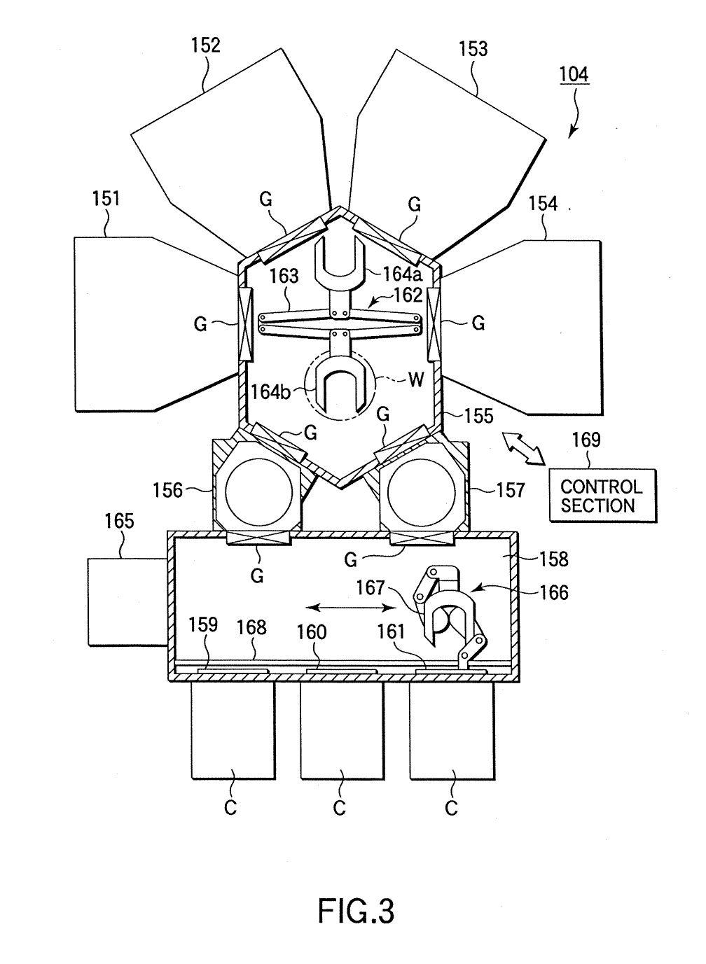

Next, a detailed explanation will be given of the etching/ashing/by-product-removing/recovering system 104, which plays an important part of this embodiment. FIG. 3 is a plan view schematically showing the structure of the etching/ashing/by-product-removing/recovering system 104. The etching/ashing/by-product-removing/recovering system 104 includes an etching unit 151 for performing plasma etching, an ashing unit 152 for performing plasma ashing, a by-product-removing unit 153 for removing a by-product by use of plasma, and a silylation unit (SCH) 154. These units 151 to 154 are disposed to respectively correspond to four sides of a hexagonal wafer transfer chamber 155. The other two sides of the wafer transfer chamber 155 are respectively connected to load-lock chambers 156 and 157. A wafer I/O (in/out) chamber 158 is connected to the load-lock chambers 156 and 157 on the side opposite to the wafer transfer chamber 155. The wafer I/O chamber 158 has three ports 159, 160, and 161 on the side opposite to the load-lock chambers 156 and 157, wherein the ports are used for respectively connecting three carriers C that can contain wafers W.

The etching unit 151, ashing unit 152, by-product-removing unit 153, silylation unit (SCH) 154, and load-lock chambers 156 and 157 are connected to the sides of the wafer transfer chamber 155 respectively through gate valves G, as shown in FIG. 3. Each of these units and chambers communicates with the wafer transfer chamber 155 when the corresponding gate valve G is opened, and is blocked from the wafer transfer chamber 155 when the corresponding gate valve G is closed. Gate valves G are also disposed between the load-lock chambers 156 and 157 and the wafer I/O chamber 158. Each of the load-lock chambers 156 and 157 communicates with the wafer I/O chamber 158 when the corresponding gate valve G is opened, and is blocked from the wafer I/O chamber 158 when the corresponding gate valve G is closed.

The wafer transfer chamber 155 is provided with a wafer transfer unit 162 disposed therein, for transferring wafers W to and from the etching unit 151, ashing unit 152, by-product-removing unit 153, silylation unit (SCH) 154, and load-lock chambers 156 and 157. The wafer transfer unit 162 is disposed essentially at the center of the wafer transfer chamber 155. The wafer transfer unit 162 includes two rotation/stretch portions 163, which are rotatable and extensible/contractible. Two blades 164a and 164b, each for supporting a wafer W, are respectively connected to the distal ends of the rotation/stretch portions 163. The two blades 164a and 164b are connected to the rotation/stretch portions 163 to face opposite directions. The interior of the wafer transfer chamber 155 can be maintained at a predetermined vacuum level.

Each of the three ports 159, 160, and 161 of the wafer I/O chamber 158 for connecting a carrier C is provided with a shutter (not shown). A carrier C, which contains wafers W or is empty, is directly connected to each of the ports 159, 160, and 161, and the shutter is then opened for the carrier C to communicate with the wafer I/O chamber 158 while preventing inflow of outside air. An alignment chamber 165 for performing alignment of a wafer W is disposed on one side of the wafer I/O chamber 158.

The wafer I/O chamber 158 is provided with a wafer transfer unit 166 disposed therein, for transferring wafers W to and from the carriers C and load-lock chambers 156 and 157. The wafer transfer unit 166 includes articulated arm structures respectively having hands 167 at the distal ends. The wafer transfer unit 166 is movable on a rail 168 in a direction in which the carriers C are arrayed, to transfer a wafer W placed on each of the hands 167 at the distal ends. A control section 169 is arranged to control the operation of the wafer transfer units 162 and 166 and the entire system.

Next, an explanation will be given of the respective units. At first, the etching unit 151 will be explained.

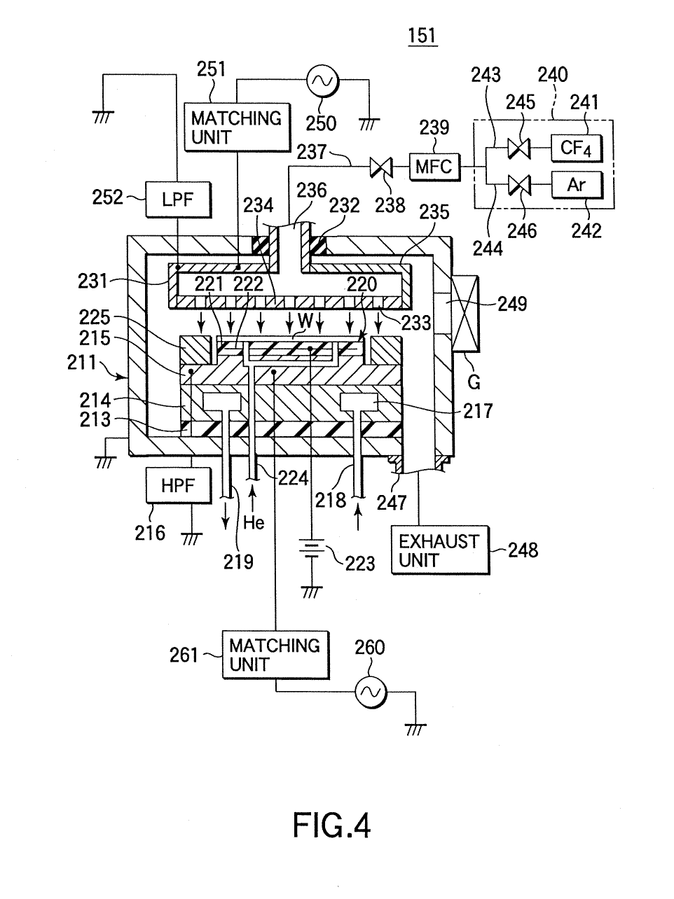

The etching unit 151 is arranged to perform plasma etching on an Si-containing low dielectric constant film (which will be referred to as an Si-containing Low-k film) formed as an inter-level insulating film. As shown in FIG. 4, the etching unit 151 includes an essentially cylindrical process chamber 211. The process chamber 211 is provided with a susceptor 215 disposed therein on the bottom through an insulating plate 213 and a susceptor pedestal 214 in this order. The susceptor 215 is used as a lower electrode and has a top face provided with an electrostatic chuck 220, on which a wafer W is placed. A reference numeral 216 denotes a high-pass filter (HPF).

The susceptor pedestal 214 is provided with a temperature adjusting medium space 217 formed therein for circulating a temperature adjusting medium to adjust the susceptor 215 to a predetermined temperature. The temperature adjusting medium space 217 is connected to a supply line 218 and an exhaust line 219.

The electrostatic chuck 220 has a structure in which an electrode 222 is sandwiched between insulating layers 221. When a DC (direct current) voltage is applied from a DC power supply 223 to the electrode, the wafer W is attracted and held on the electrostatic chuck 222 by an electrostatic force. Further, a heat transmission gas, such as He gas, is supplied through a gas passage 224 to the bottom of the wafer W. The temperature of the wafer W is adjusted to a predetermined value through the heat transmission gas. An annular focus ring 225 is disposed on the top of the susceptor 215 at the rim to surround the wafer W placed on the electrostatic chuck 220.

An upper electrode 231 is disposed above the susceptor 215 to face the susceptor 215, and is supported inside the plasma process chamber 211 through an insulating body 232. The upper electrode 231 includes an electrode plate 234 having a number of gas delivery holes 233, and an electrode support 235 supporting the electrode plate 234, such that they form a shower structure.

The electrode support 235 has a gas feed port 236 formed therein at the center, which is connected to a gas supply line 237. The gas supply line 237 is connected to a process gas supply source 240 for supplying an etching process gas through a valve 238 and a mass-flow controller 239. The process gas supply source 240 is arranged to supply an F-containing gas, such as CF₄ gas used in this embodiment, into the chamber 211. Specifically, the process gas supply source 240 includes a CF₄ gas supply source 241 and an Ar gas supply source 242, which are respectively connected to a CF₄ gas line 243 and an Ar gas line 244. The CF₄ gas line 243 and Ar gas line 244 are respectively provided with valves 245 and 246.

The bottom of the process chamber 211 is connected to an exhaust unit 248 through an exhaust line 247. The exhaust unit 248 includes a vacuum pump, such as a turbo molecular pump, to set the interior of the process chamber 211 at a predetermined vacuum atmosphere. The process chamber 211 has a transfer port 249 formed in a side wall and provided with a gate valve G for opening/closing the port, as described above.

The upper electrode 231 is connected to a first RF (radio frequency) power supply 250 through a first matching unit 251 to supply an RF power for plasma generation. The upper electrode 231 is further connected to a low-pass filter (LPF) 252. On the other hand, the lower electrode or susceptor 215 is connected to a second RF power supply 260 through a second matching unit 261 to attract ions in plasma.

In the etching unit 151 thus structured, an etching process gas comprising CF₄ gas and Ar gas is supplied from the process gas supply source 240 into the chamber 211. The CF₄ gas and Ar gas thus supplied are turned into plasma by an RF power applied from the first RF power supply 250. This plasma is used to etch an Si-containing Low-k film to form grooves or holes. At this time, an RF power is applied from the second RF power supply 260 to the susceptor 215 to attract ions, thereby performing anisotropic etching.

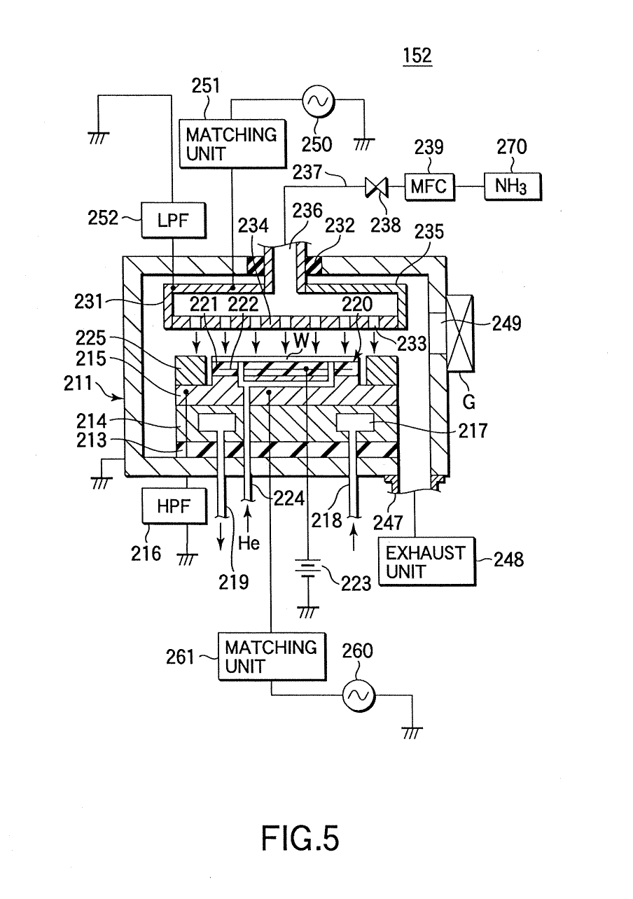

Next, an explanation will be given of the ashing unit 152 with reference to the schematic sectional view shown in FIG. 5. The ashing unit 152 has essentially the same structure as the etching unit 151 except for the gas supply system. In the following explanation, the constituent elements having substantially the same function and arrangement as those shown in FIG. 4 are denoted by the same reference numerals, and a repetitive description will be made only when necessary.

The ashing unit 152 is connected through a gas supply line 237 to an NH₃ gas supply source 270 to supply NH₃ gas used as an ashing gas into a process chamber 211.

In the ashing unit 152, an ashing gas comprising NH₃ gas is supplied from the NH₃ gas supply source 270 into the chamber 211. The NH₃ gas thus supplied is turned into plasma by an RF power applied from a first RF power supply 250. This plasma is used to incinerate and thereby remove the resist film and so forth after etching. At this time, an RF power is applied from a second RF power supply 260 to a susceptor 215 to attract ions, thereby assisting the ashing.

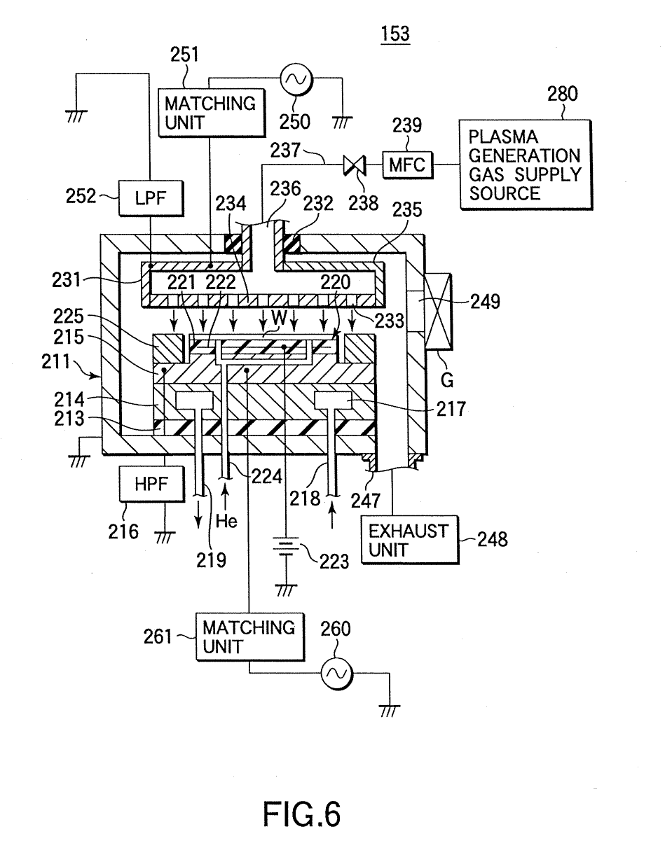

Next, an explanation will be given of the by-product-removing unit 153 with reference to the schematic sectional view shown in FIG. 6. When Si contained in the Si-containing Low-k film, F contained in the etching gas, and NH₃ contained in the ashing gas react with each other, silicon fluoride ammonium is produced as a by-product. The by-product-removing unit 153 is arranged to remove silicon fluoride ammonium thus produced on etched portions of the Si-containing Low-k film, as described later. The by-product-removing unit 153 has essentially the same structure as the etching unit 151 except for the gas supply system. In the following explanation, the constituent elements having substantially the same function and arrangement as those shown in FIG. 4 are denoted by the same reference numerals, and a repetitive description will be made only when necessary.

The by-product-removing unit 153 is connected through a gas supply line 237 to a plasma generation gas supply source 280 to supply a plasma generation gas into a process chamber 211. The plasma generation gas may be selected from the group consisting of H₂ gas, Ar gas, and He gas.

In the by-product-removing unit 153, a plasma generation gas, such as H₂ gas, Ar gas, or He gas, is supplied from the plasma generation gas supply source 280 into the chamber 211. The plasma generation gas thus supplied is turned into plasma by an RF power applied from a first RF power supply 250. This plasma is used to etch and thereby remove silicon fluoride ammonium produced as a by-product on etched portions of the Si-containing Low-k film. At this time, the RF power applied from the second RF power supply 260 is adjusted in accordance with the plasma generation gas. For example, where H₂ gas, which has a small atomicity, is used, there is no need to attract ions, but where Ar gas, which has a large atomicity, is used, an RF power is applied from the second RF power supply 260 to the susceptor 215 to reliably remove the by-product.

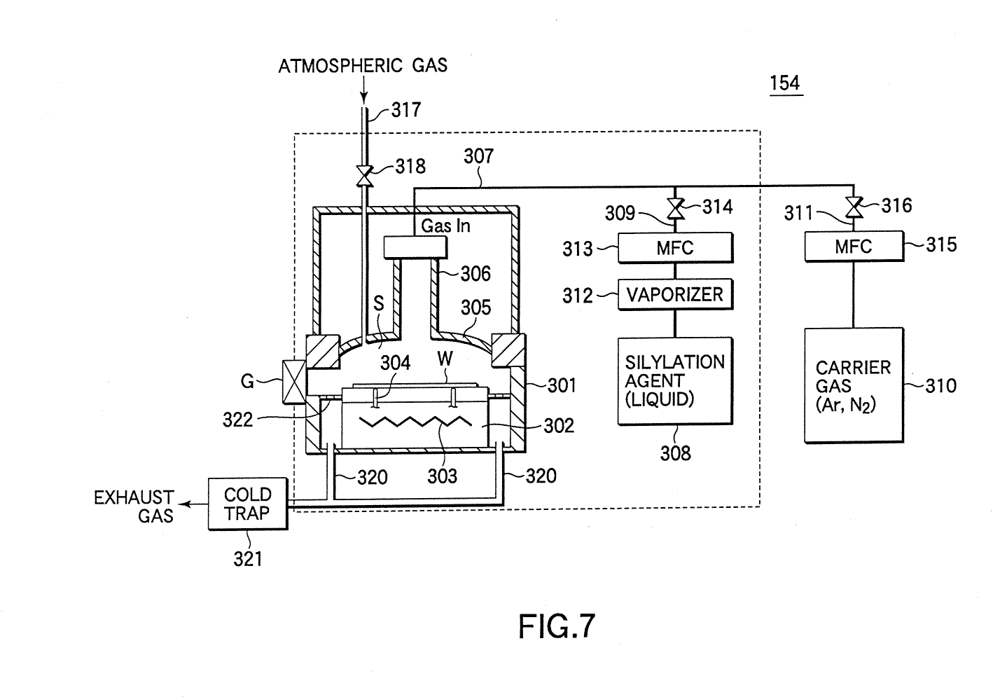

Next, a detailed explanation will be given of the silylation unit (SCH) 154 with reference to the schematic sectional view shown in FIG. 7. The silylation unit (SCH) 154 includes a chamber 301 for accommodating a wafer W. The chamber 301 is provided with a wafer table 302 disposed therein at the bottom. The wafer table 302 includes a heater 303 built therein, by which the wafer W placed on the wafer table 302 can be heated at a predetermined temperature. The wafer table 302 is provided with wafer lifter pins 304, which can project and retreat to and from the top face. The lifter pins 304 can place the wafer W at a predetermined position above and separated from the wafer table 302, when the wafer W is transferred to and from the wafer table 302.

The chamber 301 contains an internal container 305, which defines a narrow process space S for accommodating the wafer W. A silylation agent (silylation gas) is supplied into this process space S. The internal container 305 has a gas feed passage 306 formed at the center and extending in a vertical direction.

The top of the gas feed passage 306 is connected to a gas supply line 307. The gas supply line 307 is connected to a line 309 extending from a silylation agent supply source 308 for supplying a silylation agent, such as DMSDMA (Dimethylsilyldimethylamine), and a line 311 extending from a carrier gas supply source 310 for supplying a carrier gas, such as Ar or N₂ gas. The line 309 is provided with a vaporizer 312 for vaporizing the silylation agent, a mass-flow controller 313, and a switching valve 314 disposed thereon in this order from the silylation agent supply source 308. The line 311 is provided with a mass-flow controller 315 and a switching valve 316 disposed thereon in this order from the carrier gas supply source 310. The silylation agent vaporized by the vaporizer 312 is carried by the carrier gas and is supplied through the gas supply line 307 and gas feed passage 306 into the process space S defined by the internal container 305. When the process is performed, the wafer W is heated by the heater 303 to a predetermined temperature. In this case, the wafer temperature can be controlled within a range of, e.g., from a room temperature to 300° C.

An atmospheric gas supply line 317 is disposed to extend from the atmospheric environment outside the chamber 301 to the internal container 305 inside the chamber 301. The atmospheric gas supply line 317 is provided with a valve 318 disposed thereon. When the valve 318 is opened, atmospheric gas comes into the process space S defined by the internal container 305 inside the chamber 301, thereby supplying moisture. The etching/ashing/by-product-removing/recovering system 104 is arranged to sequentially perform the etching, ashing, removing, and recovering processes in a vacuum atmosphere. Accordingly, the space accommodating the wafer W scarcely contains moisture as it is, and thus may suffer a difficulty in causing the silylation reaction. In light of this, the control section 169 (see FIG. 3) is preferably arranged to perform control such that, before starting supply of the silylation agent, the valve 318 on the atmospheric gas supply line 317 is opened to supply atmospheric gas so that moisture is adsorbed on the wafer W to promote the silylation reaction. In order to supply a suitable amount of moisture for the silylation reaction, the wafer W on the wafer table 302 is preferably heated by the heater 303 to perform moisture adjustment after moisture is adsorbed, and then the silylation agent is supplied. At this time, the heating temperature is preferably set to be 50 to 200° C. Further, in order to promote the silylation reaction, the wafer W may be heated also after starting supply of the silylation agent.

The chamber 301 has a gate valve G disposed on the sidewall. When the gate valve G is opened, the wafer W is transferred to and from the chamber 301. The bottom of the chamber 301 is connected to a vacuum pump (not shown) through an exhaust line 320 disposed at the periphery. The interior of the chamber 301 is exhausted by the vacuum pump through the exhaust line 320 and thereby controlled to have a pressure of, e.g., 10 Torr (266 Pa) or less. A cold trap 321 is disposed on the exhaust line 320. A baffle plate 322 is disposed between an upper portion of the wafer table 302 and the chamber wall.

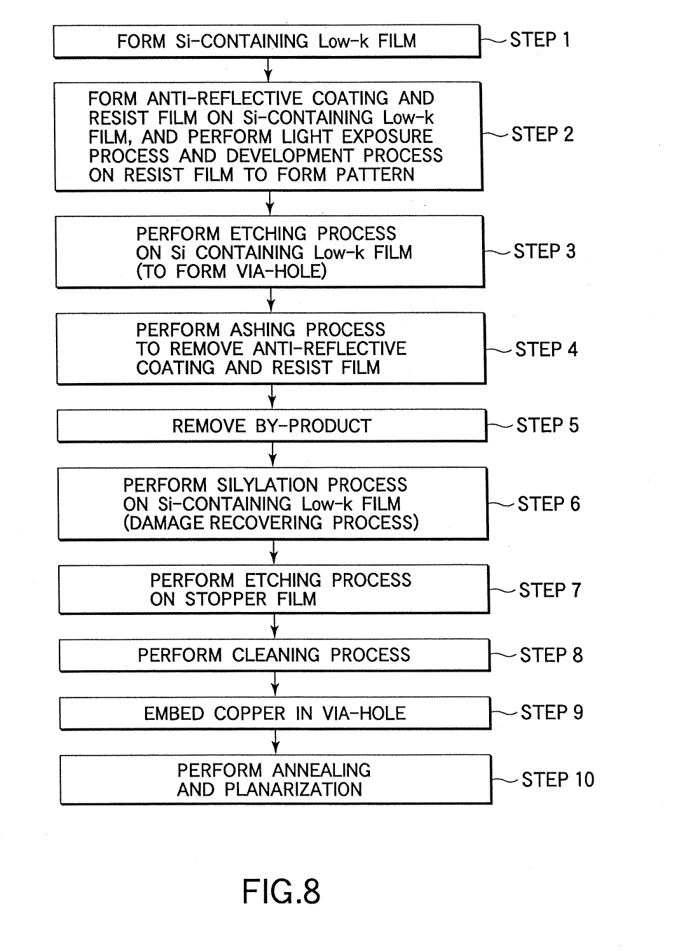

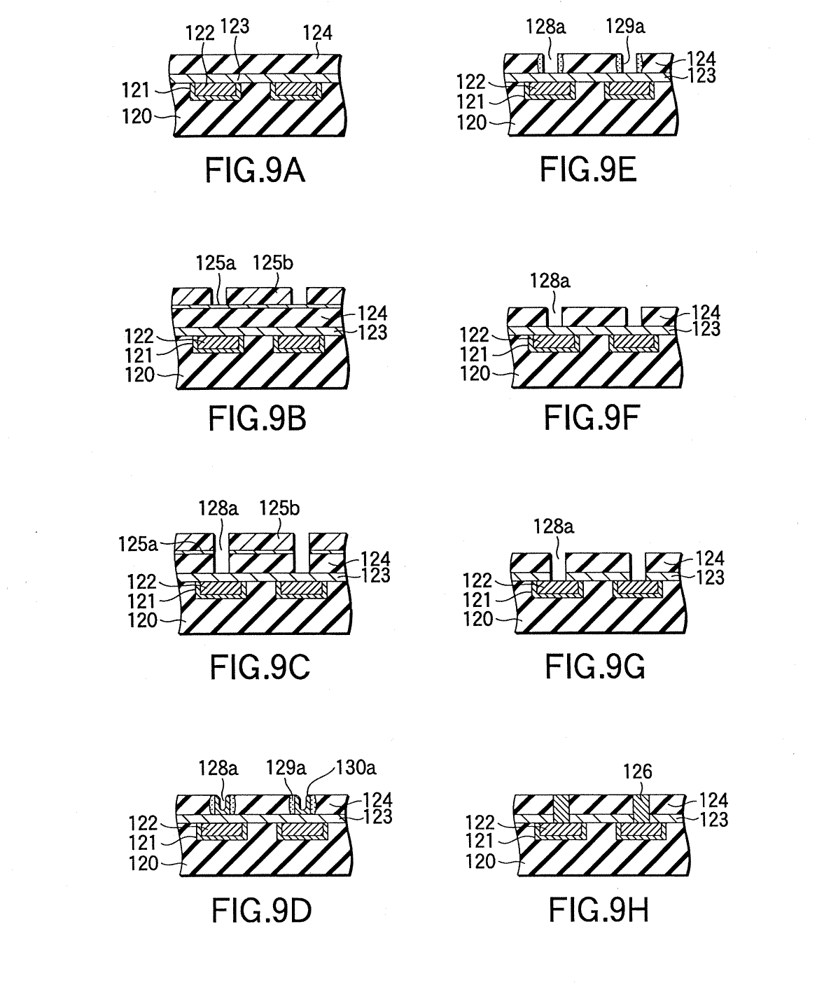

Next, an explanation will be given of a semiconductor device manufacturing process employing a single damascene method, performed by the semiconductor device manufacturing system shown in FIG. 2. FIG. 8 is a flowchart showing a manufacturing process of this kind. FIGS. 9A to 9H are sectional views showing steps of the flow shown in FIG. 8.

At first, a wafer W is prepared from an Si substrate (not shown) as follows. Specifically, an insulating film 120 is disposed on the substrate. A lower interconnection line 122 made of copper is disposed at an upper portion in the insulating film 120 with a barrier metal layer 121 interposed therebetween. A stopper film (such as an SiN film or SiC film) 123 is disposed on the insulating film 120 and lower interconnection line 122 made of copper. Then, the wafer W is transferred into the SOD apparatus 101, in which an Si-containing Low-k film 124 is formed on the stopper film 123 (STEP 1). Consequently, the state shown in FIG. 9A is obtained.

Then, the wafer W with the Si-containing Low-k film 124 thus formed thereon is transferred into the resist coating/developing apparatus 102, in which an anti-reflective coating 125a and a resist film 125b are sequentially formed on the Si-containing Low-k film 124. Then, the wafer W is transferred into the light exposure apparatus 103, in which the wafer W is subjected to a light exposure process with a predetermined pattern. Then, the wafer W is transferred back into the resist coating/developing apparatus 102, in which the resist film 125b is subjected to a development process by the developing unit to form a predetermined circuit pattern on the resist film 125b (STEP 2). Consequently, the state shown in FIG. 9B is obtained.

Then, the wafer W is transferred into the etching/ashing/by-product-removing/recovering system 104. In this system, the wafer W is first transferred into the etching unit 151, in which a plasma etching process is performed on the Si-containing Low-k film 124 (STEP 3). Consequently, a via-hole 128a reaching the stopper film 123 is formed in the Si-containing Low-k film 124 (FIG. 9C). In this etching, CF₄ gas employed as an F-containing gas and Ar gas are used, although this is not limiting, as long as an F-containing gas is contained.

The wafer W thus treated by the etching process is transferred into the ashing unit 152, in which a plasma ashing process is performed to remove the anti-reflective coating 125a and resist film 125b (STEP 4 and FIG. 9D). In this ashing process, NH₃ gas is used as a process gas.

After the anti-reflective coating 125a and resist film 125b are removed by plasma ashing, as described above, the sidewall of the via-hole 128a formed in the Si-containing Low-k film 124 bears damaged portions 129a, as shown in FIG. 9D, because it has been damaged by the etching and ashing. Although FIG. 9D schematically shows the damaged portions 129a, the boundary between each of the damaged portions 129a and non-damaged portion is not clear unlike the drawings. If the via-hole 128a with a damaged portion 129a formed in the sidewall is filled with a metal material to form a connection line, problems arise such that the parasitic capacitance between interconnection lines is increased, so a signal delay occurs and the insulation between interconnection lines is deteriorated.

Accordingly, after the resist film and so forth are removed, in order to recover the damage of the Si-containing Low-k film 124, the wafer W is transferred into the silylation unit 154 to perform a silylation process. However, as in this embodiment, where etching is performed on the Si-containing Low-k film 124 by use of an F-containing gas, and then ashing is performed by use of NH₃ gas, a subsequent silylation process directly performed cannot work well to recover damage. As a result of studying the causes of this problem, it has been found that this is due to a silicon fluoride ammonium family by-product 130a, which has been produced by a reaction of Si, F, and NH₃ on etched portions, such as the inner surface of the via-hole 128a. As shown in FIG. 9D, where the by-product 130a is formed on the surface of the damaged portions 129a, the by-product causes a side reaction with a silylation agent. This side reaction significantly hinders the silylation agent from performing the silylation reaction (repairing effect), so the damaged portions 129a cannot be sufficiently subjected to damage recovering.

Accordingly, in this embodiment made in light of the problem described above, the by-product-removing unit 153 is used to etch and thereby remove the by-product by a plasma process (STEP 5 and FIG. 9E) prior to the silylation process.

In the by-product-removing unit 153, a plasma generation gas is supplied from the plasma generation gas supply source 280 through the upper electrode 231 into the chamber 211. The plasma generation gas thus supplied is turned into plasma by an RF power applied from the first RF power supply 250. This plasma is used to etch and thereby remove silicon fluoride ammonium produced as the by-product 130a on etched portions of the Si-containing Low-k film 214, such as the inner surface of the via-hole 128a. The plasma generation gas may be selected from the group consisting of H₂ gas, Ar gas, and He gas. In this case, the pressure inside the chamber 211 is preferably set to be about 10 to 20 Pa, and the flow rate of the plasma generation gas is preferably set to be about 300 to 500 mL/min (sccm). The application RF power is preferably set to have a frequency of 60 MHz and a power of about 300 W, for example. Where Ar gas, which has a large atomicity, is used as the plasma generation gas, an RF power is applied from the second RF power supply 260 to the lower electrode or susceptor 215 to attract ions in plasma, in order for Ar gas to effectively act on the by-product. For example, this RF power applied from the second RF power supply 260 is preferably set to have a frequency of 2 MHz and a power of about 300 W.

After the processes described above, the silylation process is performed while the silylation agent is supplied (STEP 6 and FIG. 9F). Accordingly, the damage recovery of the Si-containing Low-k film 124 is promoted, so that, even where the resist film 125b and so forth are removed by a process that can cause heavy damage, such as plasma ashing, the specific dielectric constant of the Si-containing Low-k film 124 is returned to a state near the initial state.

Where the silylation process is performed in the silylation unit 154, at first, the gate valve G is opened. Then, the wafer W is transferred into the chamber 301 and placed on the wafer table 302. Then, the wafer W is heated by the heater 303 to a predetermined temperature and the pressure inside the chamber 301 is reduced to a predetermined pressure. In this state, the silylation agent vaporized by the vaporizer is carried by a carrier gas onto the wafer W. The conditions of the silylation process in the silylation unit 154 are suitably selected in accordance with the type of the silylation agent (silylation gas), as follows. For example, the temperature of the vaporizer 312 is set to be from a room temperature to 200° C. The silylation agent flow rate is set to be 700 sccm (mL/min) or less. The process pressure is set to be 10 mTorr to 100 Torr (1.33 to 13,330 Pa). The temperature of the table 302 is set to be from a room temperature to 200° C.

Where DMSDMA is used as the silylation agent, the following method may be used, for example. Specifically, the temperature of the table 302 is set at a predetermined temperature by the heater 303, and the pressure inside the chamber 301 is decreased to about 650 to 700 Pa. Then, DMSDMA vapor carried by a carrier gas is supplied into the chamber 301 until the inner pressure reaches about 6,500 to 7,500 Pa. Then, the process is performed for, e.g., three minutes, while maintaining the pressure. The silylation reaction using DMSDMA is expressed by the following reaction formula 1.

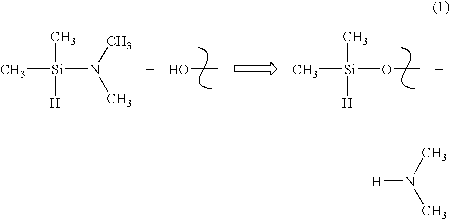

The silylation agent is not limited to DMSDMA described above, and the agent may comprise any substance as long as it causes a silylation reaction. However, it is preferable to use a substance having a relatively small molecular structure selected from the compounds including silazane bonds (Si—N bonds) in molecules, such as a substance having a molecular weight preferably of 260 or less, and more preferably of 170 or less. Namely, examples other than DMSDMA and HMDS are TMSDMA (Dimethylaminotrimethylsilane), TMDS (1,1,3,3-Tetramethyldisilazane), TMSPyrole (1-Trimethylsilylpyrole), BSTFA (N,O-Bis(trimethylsilyl)trifluoroacetamide), and BDMADMS (Bis(dimethylamino)dimethylsilane). The chemical structures of these substances are as follows.

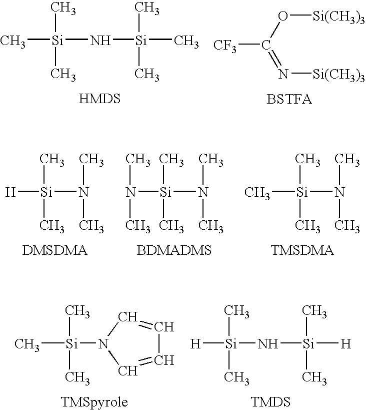

Of the compound set out above, TMSDMA and TMDS are preferably used, because they are high in the effect of recovering the dielectric constant, and the effect of decreasing the leakage current. Further, in light of the stability after silylation, it is preferable to use a substance (such as TMSDMA or HMDS) having a structure in which Si of each silazane bond is bonded to three alkyl groups (such as methyl groups).

As described above, in order to promote the silylation reaction, the following control is preferably executed. Specifically, before the silylation agent is supplied, the valve 318 on the atmospheric gas supply line 317 is opened to supply atmospheric gas so that moisture is adsorbed on the wafer W. Thereafter, the wafer W on the wafer table 302 is heated by the heater 303 to perform moisture adjustment, and then the silylation agent is supplied. At this time, the heating temperature is preferably set to be 50 to 200° C. Further, in order to promote the silylation reaction, the wafer W is preferably heated by the heater 303 also after starting supply of the silylation agent. In the latter heating, the wafer temperature is preferably set to be 50 to 200° C. to attain the effect of suitably promoting the reaction.

The wafer W thus treated by the silylation process is then subjected to an etching process to remove the stopper film 123 (STEP 7 and FIG. 9G). At this time, the etching may be performed by an etching apparatus located outside the system or by the etching unit 151 described above. Where the etching unit 151 is to be used for this purpose, the process gas supply source 240 is arranged in advance to supply an etching process gas for the stopper film 123 as well.

Then, the wafer W is transferred into the cleaning apparatus 105, in which a cleaning process is performed on the wafer W (STEP 8). The Si-containing Low-k film 124 may be damaged by the etching process and/or cleaning process. In this case, a silylation process may be performed in the same manner as described above.

Thereafter, the wafer W is transferred into the sputtering apparatus 106, in which a barrier metal film and a Cu seed layer are formed on the inner surface of the via-hole 128a. Then, the wafer W is transferred into the electrolytic plating apparatus 107, in which copper 126 used as an interconnection line metal is embedded in the via-hole 128a (STEP 9 and FIG. 9H). Then, the wafer W is subjected to a heat process to perform an annealing process on the copper 126 embedded in the via-hole 128a (no annealing apparatus is shown in FIG. 2). Then, the wafer W is transferred into the CMP apparatus 108, in which a planarization process is performed on the wafer W by a CMP method (STEP 10). Consequently, a predetermined semiconductor device is manufactured.

In the semiconductor device manufacturing method described above, the by-product produced on etched portions of the etching target or Si-containing Low-k film is removed before the silylation process is performed to recover the damage. Thus, the recovering process can reliably provide its effect, and the specific dielectric constant of the film is thereby sufficiently recovered, even if a resist film or the like is removed by a process that can cause heavy damage, such as an ashing process. Consequently, it is possible to provide a semiconductor device with excellent electrical characteristics, and to thereby improve the reliability of the semiconductor device.

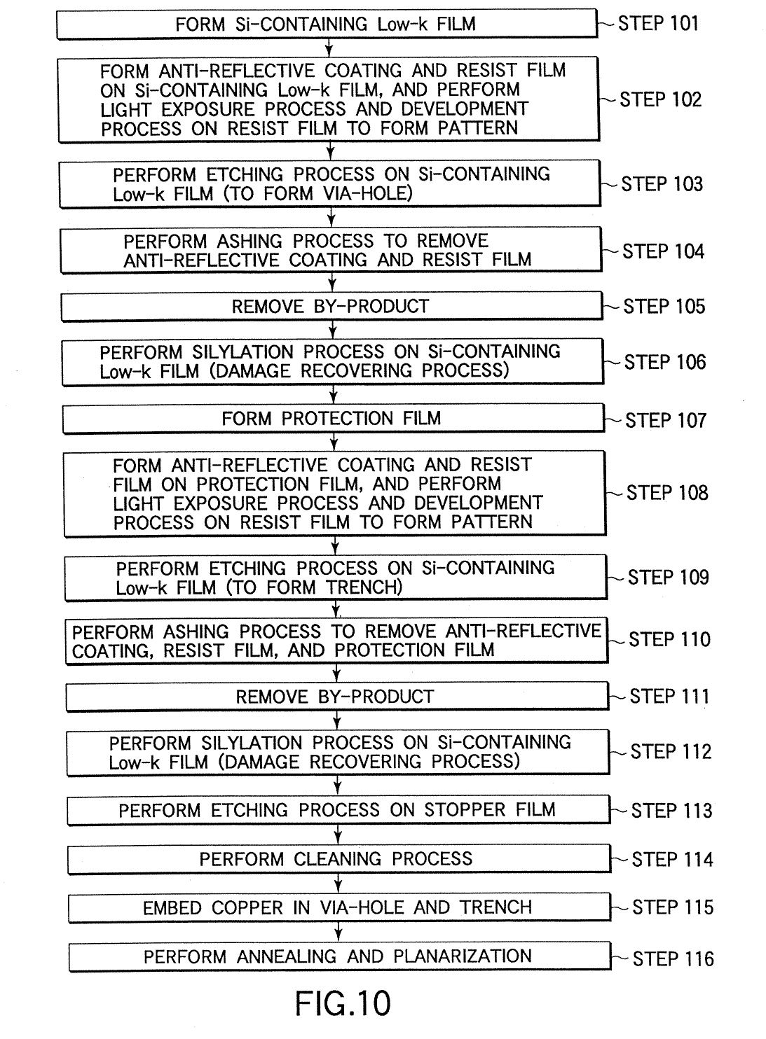

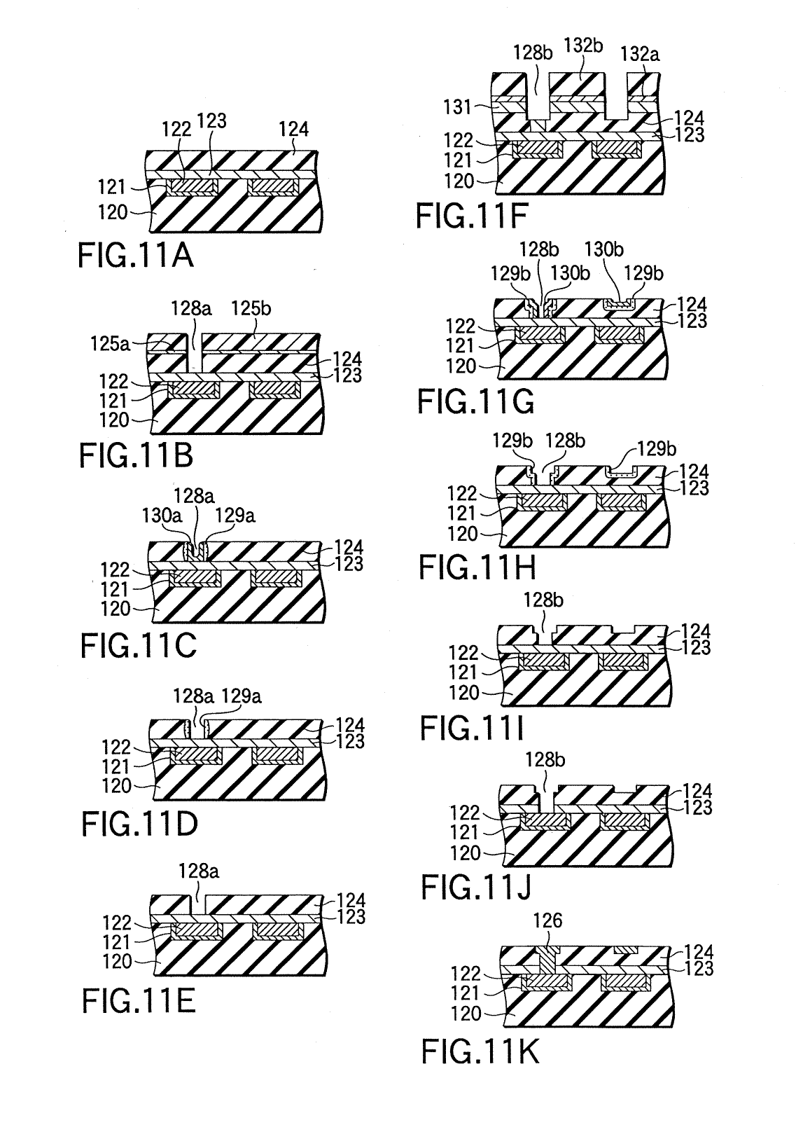

Next, an explanation will be given of a semiconductor device manufacturing process employing a dual damascene method, performed by the semiconductor device manufacturing system shown in FIG. 2. FIG. 10 is a flowchart showing a manufacturing process of this kind. FIGS. 11A to 11K are sectional views showing steps of the flow shown in FIG. 10. In this embodiment, the apparatuses used in the respective steps will not be explained, because they have been clarified by the preceding explanation.

At first, as in the case using a single damascene method described above, a wafer W is prepared from an Si substrate (not shown) as follows. Specifically, an insulating film 120 is disposed on the substrate. A lower interconnection line 122 made of copper is disposed at an upper portion in the insulating film 120 with a barrier metal layer 121 interposed therebetween. A stopper film (such as an SiN film or SiC film) 123 is disposed on the insulating film 120 and lower interconnection line 122 made of copper. Then, an Si-containing Low-k film 124 is formed on the stopper film 123 on this wafer W (STEP 101 and FIG. 11A).

Then, an anti-reflective coating 125a and a resist film 125b are sequentially formed on the Si-containing Low-k film 124. Then, the wafer W is subjected to a light exposure process with a predetermined pattern. Then, the resist film 125b is subjected to a development process to form a predetermined circuit pattern on the resist film 125b (STEP 102). Then, an etching process is performed by use of plasma of an F-containing gas, such as CF₄ gas, while using the resist film 125b as an etching mask, to form a via-hole 128a reaching the stopper film 123 (STEP 103). Consequently, the state shown in FIG. 11B is obtained.

Then, an ashing process is performed by use of plasma of NH₃ gas to incinerate and thereby remove the anti-reflective coating 125a and resist film 125b (STEP 104 and FIG. 11C).

After the anti-reflective coating 125a and resist film 125b are removed by plasma ashing, as described above, the sidewall of the via-hole 128a formed in the Si-containing Low-k film 124 bears damaged portions 129a, as shown in FIG. 11C, because it has been damaged by the etching and ashing, as in the former case. Accordingly, after the resist film and so forth are removed, in order to recover the damage of the Si-containing Low-k film 124, a silylation process is performed as a recovering process on the wafer W, as in the former case. However, since Si contained in the Si-containing Low-k film 124, F contained in the etching gas, and NH₃ contained in the ashing gas react with each other, silicon fluoride ammonium has been produced as a by-product 130a on the etched portions, such as the inner surface of the via-hole 128a, after the ashing.

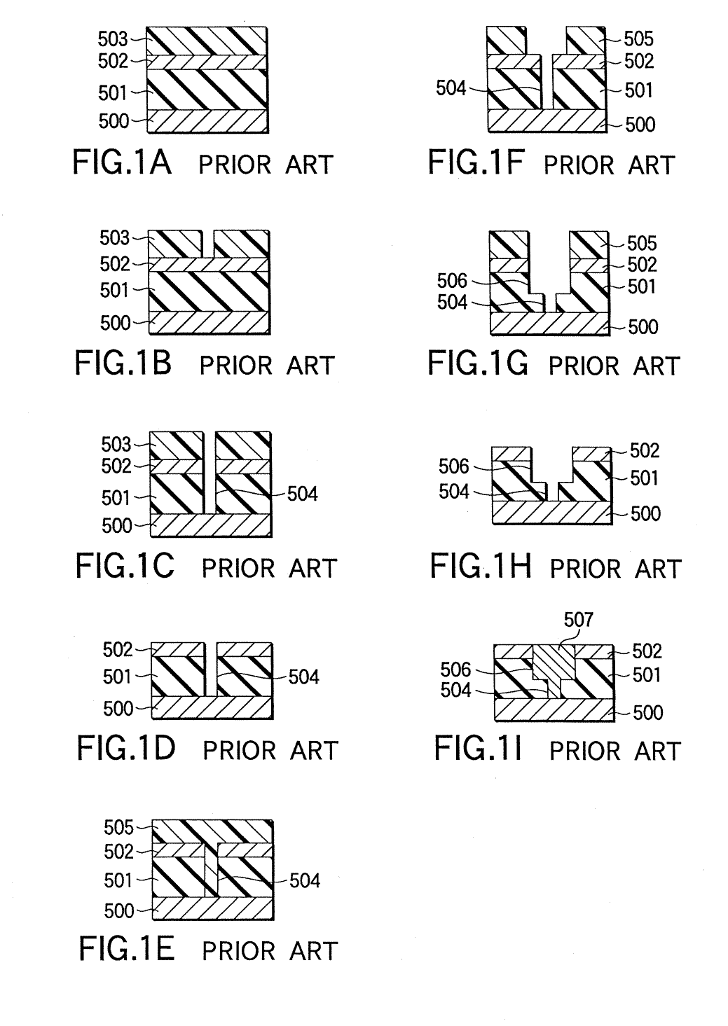

Accordingly, as in the process shown in FIG. 8 described above, a by-product-removing process is performed (STEP 105 and FIG. 1D) prior to the silylation process used as a recovering process. The by-product-removing process is performed by use of the plasma process described above under the same conditions.

After the by-product is thus removed, the silylation process is performed to recover the damage (STEP 106 and FIG. 11E). This process may be performed under the same conditions as those described above.

Then, a protection film (sacrificial film) 131 is formed on the surface of the Si-containing Low-k film 124 (STEP 107). Then, an anti-reflective coating 132a and a resist film 132b are sequentially formed on the protection film 131. Then, the resist film 132b is subjected to a light exposure process with a predetermined pattern, and then to a development process to form a circuit pattern on the resist film 132b (STEP 108). Then, an etching process is performed by use of an F-containing gas, such as CF₄ gas, while using the resist film 132b as an etching mask to form a trench 128b in the Si-containing Low-k film 124 (STEP 109). Consequently, the state shown in FIG. 11F is obtained.

The protection film 131 can be formed from a predetermined chemical solution applied by spin coating in the SOD apparatus 101. The protection film 131 is not necessarily required, so the anti-reflective coating 132a and resist film 132b may be formed directly on the Si-containing Low-k film 124.

Then, an ashing process is performed by use of plasma of NH₃ gas to incinerate and thereby remove the anti-reflective coating 132a, resist film 132b, and protection film 131 (STEP 110 and FIG. 11G).

After the anti-reflective coating 132a, resist film 132b, and protection film 131 are removed by plasma ashing, as described above, the sidewall of the trench 128b formed in the Si-containing Low-k film 124 bears damaged portions 129b, as shown in FIG. 11G, because it has been damaged by the etching and ashing, as in the former case. Accordingly, a silylation process is then performed to recover the damage. However, since Si contained in the Si-containing Low-k film 124, F contained in the etching gas, and NH₃ contained in the ashing gas react with each other, silicon fluoride ammonium has been produced as a by-product 130b on the etched portions, such as the inner surface of the trench 128b, after the ashing, as in the case of the via-hole 128a.

Accordingly, as in the case of the via-hole, a by-product-removing process is performed (STEP 111 and FIG. 11H) prior to the silylation process used as a recovering process. The by-product-removing process may be performed by use of the plasma process described above under the same conditions.

After the by-product is thus removed, the silylation process is performed to recover the damage (STEP 112 and FIG. 11I). This process is performed under the same conditions as those described above.

Then, the wafer W thus treated by the silylation process is subjected to an etching process to remove the stopper film 123 (STEP 113 and FIG. 11J), and then to a cleaning process (STEP 114). The Si-containing Low-k film 124 may be damaged by the etching process and/or cleaning process. In this case, a silylation process may be performed in the same manner as described above.

Thereafter, a barrier metal film and a Cu seed layer (i.e., plating seed layer) are formed on the inner surface of the trench 128b and via-hole 128a. Then, copper 126 used as an interconnection line metal is embedded in the trench 128b and via-hole 128a by an electrolytic plating apparatus (STEP 115 and FIG. 11K). Then, the wafer W is subjected to a heat process to perform an annealing process on the copper 126 embedded in the trench 128b and via-hole 128a (no annealing apparatus is shown in FIG. 2). Then, the wafer W is transferred into the CMP apparatus 108, in which a planarization process is performed on the wafer W by a CMP method (STEP 116). Consequently, a predetermined semiconductor device is manufactured.

As described above, also in a case where a dual damascene method is used to manufacture a semiconductor device, the by-product produced on etched portions of the etching target or Si-containing Low-k film is removed before the silylation process is performed to recover the damage, as in the case where a single damascene method is used. Thus, the recovering process can reliably provide its effect, and the specific dielectric constant of the film is thereby sufficiently recovered. Consequently, it is possible to provide a semiconductor device with excellent electrical characteristics, and to thereby improve the reliability of the semiconductor device.

In this embodiment, the etching/ashing/by-product-removing/recovering system 104 includes the etching unit 151, ashing unit 152, by-product-removing unit 153, and silylation unit 154 for a recovering process, disposed independently of each other. However, the ashing unit 152 may be designed to further perform the removing process, or to further perform the removing process and silylation process. Specifically, where the process gas supply source 240 is arranged to supply NH₃ gas used as an ashing gas and a plasma generation gas for removing the by-product, the source 240 can be used to first supply NH₃ gas to perform ashing, and then switch it to the gas for removing the by-product to perform the by-product-removing process. Where the process gas supply source 240 is arranged to supply NH₃ gas used as an ashing gas, a plasma generation gas for removing the by-product, and a silylation agent for the silylation process, the source 240 can be used to first supply NH₃ gas to perform ashing, then switch it to the gas for removing the by-product to perform the by-product-removing process, and then switch it to the silylation agent to perform the silylation process.

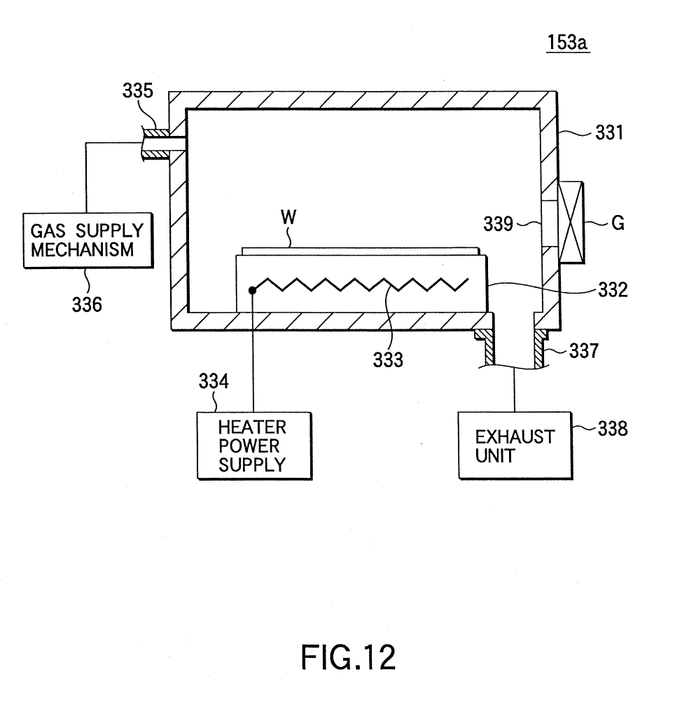

The by-product-removing process is exemplified by a plasma process performed in the by-product-removing unit 153, but another method may be used for the same purpose. For example, in place of the by-product-removing unit 153 described above, a baking unit 153a shown in FIG. 12 may be used as a by-product-removing unit to heat and thereby remove a by-product on the Si-containing Low-k film 124.

This baking unit 153a includes an essentially cylindrical process chamber 331, in which a wafer table 332 is disposed at the bottom. The wafer table 332 is provided with a heater 333 built therein, by which an annealing process is performed on a wafer W placed on the wafer table 332. The heater 333 is connected to a heater power supply 334. The wafer table 333 is provided with wafer lifter pins (not shown), which can project and retreat to and from the top face. The lifter pins 304 can place the wafer W at a predetermined position above and separated from the wafer table 332, when the wafer W is transferred to and from the wafer table 332.

At an upper position of the sidewall, the chamber 331 is connected to a gas supply mechanism 336 through a gas supply line 335, so that a predetermined atmosphere gas, such as Ar gas, is supplied from the gas supply mechanism 336 through the gas supply line 335 into the process chamber 331. The bottom of the process chamber 331 is connected to an exhaust unit 338 through an exhaust line 337. The exhaust unit 338 includes a vacuum pump, such as a turbo molecular pump, to set the interior of the process chamber 331 at a predetermined vacuum atmosphere. The process chamber 331 has a transfer port 339 formed in a side wall and provided with a gate valve G for opening/closing the port.

In this baking unit 153a, a predetermined atmosphere gas, such as Ar gas, is supplied from the gas supply mechanism 336 at a predetermined the flow rate, and the interior of the process chamber 331 is set at a pressure of, e.g., 1,000 to 1,500 Pa. In this state, the wafer W is maintained at a temperature of 150 to 350° C., such as 200° C., for 100 to 200 sec., such as 150 sec., to perform a baking process. Consequently, silicon fluoride ammonium produced as a by-product is decomposed by heat and thereby removed.

In place of the baking unit independently disposed to remove the by-product, the susceptor 215 of the ashing unit 152 may be provided with a heater to perform the baking process for removing the by-product in the ashing unit 152. Alternatively, the wafer table 302 of the silylation unit 154 may be used to perform the baking process for removing the by-product by the heater 303.

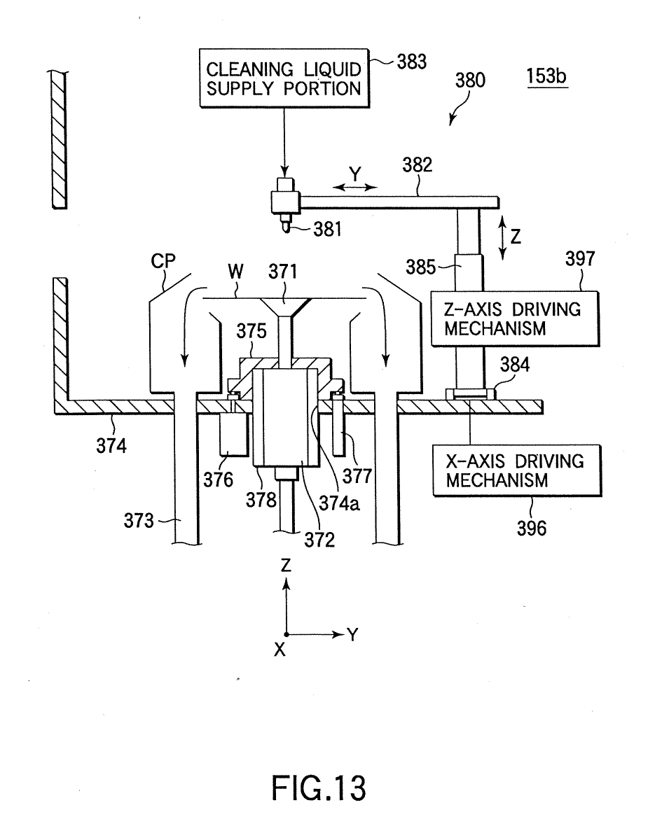

As an apparatus for removing the by-product, a further alternative type may be used. For example, a cleaning unit 153b shown in FIG. 13 may be disposed for the same purpose outside the etching/ashing/by-product-removing/recovering system 104. As this cleaning unit 153b, the cleaning unit included in the cleaning apparatus 105 may be used, or a cleaning unit may be disposed in an additional cleaning apparatus.

The cleaning unit 153b includes an annular cup CP disposed at the center, and a spin chuck 371 disposed inside the cup (CP). The spin chuck 371 is arranged to fix and hold a wafer W by means of vacuum suction, and to be rotated by a drive motor 372 in this state. A drain line 373 is disposed at the bottom of the cup (CP) to exhaust the cleaning liquid and purified water.

The drive motor 372 is disposed to be movable up and down in an opening 374a formed in the unit bottom plate 374. The drive motor 372 is coupled with an elevating mechanism 376, such as an air cylinder, and a vertical guide 377 through a cap-like flange member 375. The drive motor 372 is provided with a cylindrical cooling jacket 378 attached on its side. The flange member 375 is attached to cover the upper half of the cooling jacket 378.

A cleaning liquid supply mechanism 380 is disposed above the cup (CP) to supply a predetermined cleaning liquid onto the surface of the wafer W. The cleaning liquid is used for dissolving silicon fluoride ammonium produced as a by-product on the surface of the wafer W.

The cleaning liquid supply mechanism 380 includes a cleaning liquid delivery nozzle 381, a cleaning liquid supply portion 383, a scan arm 382, a vertical support member 385, and an X-axis driving mechanism 396. The cleaning liquid delivery nozzle 381 is arranged to deliver the cleaning liquid onto the surface of the wafer W held on the spin chuck 371. The cleaning liquid supply portion 383 is arranged to supply a predetermined cleaning liquid to the cleaning liquid delivery nozzle 381. The scan arm 382 is arranged to hold the cleaning liquid delivery nozzle 381, and to be movable back and forth in the Y-direction. The vertical support member 385 is arranged to support the scan arm 382. The X-axis driving mechanism 396 is disposed on a guide rail 384 extending in the X-axis direction on the unit bottom plate 374, and is arranged to shift the vertical support member 385 in the X-axis direction. The scan arm 382 is movable in the vertical direction (Z-direction) by a Z-axis driving mechanism 397, so that the cleaning liquid delivery nozzle 381 can be moved to an arbitrary position above a wafer W, and retreated to a predetermined position outside the cup (CP).

For example, a chemical solution of an organic solvent is used as the cleaning liquid, although the cleaning liquid is not limited to a specific one, as long as it can dissolve and remove the by-product of silicon fluoride ammonium.

In this cleaning unit 153b, after the ashing, a wafer W having the Si-containing Low-k film with silicon fluoride ammonium produced as a by-product thereon is held on the spin chuck 371 by means of vacuum suction. Then, a predetermined cleaning liquid is delivered from the cleaning liquid delivery nozzle 381 of the cleaning liquid supply mechanism 380 onto the wafer W, while the wafer W is rotated along with the spin chuck 371 by the drive motor 372, to spread the cleaning liquid all over the wafer W, thereby solving and removing the by-product.

Where the by-product-removing process is performed by a wet process in the cleaning unit 153b, a cleaning apparatus including the cleaning unit 153b may be provided with a silylation unit to perform the silylation process in this apparatus.

Next, an explanation will be given of results of experiments conducted to confirm effects of a semiconductor device manufacturing method according to the present invention. At first, samples were prepared such that a MSQ mat film was formed as an Si-containing Low-k film on a silicon wafer, and were subjected to an etching process and an ashing process.

The etching conditions used at this time were set as follows.

In-chamber pressure: 10 Pa (75 mTorr),

Upper side RF power (60 MHz): 1,500 W,

Lower side RF power (2 MHz): 100 W,

Etching gas:
CF₄ gas=80 mL/min (sccm),
Ar gas=160 mL/min (sccm), and

Etching time: 10 sec.

The ashing was performed by use of either O₂ ashing or NH₃ ashing while the conditions thereof were set as follows.

O₂ ashing:
In-chamber pressure: 1.3 Pa (10 mTorr),
Upper side RF power (60 MHz): 300 W,
Lower side RF power (2 MHz): 300 W,
Ashing gas:
   O₂ gas=300 mL/min (sccm), and
Ashing time: 26 sec.

NH₃ ashing:
n-chamber pressure: 40 Pa (300 mTorr),
Upper side RF power (60 MHz): 0 W,
Lower side RF power (2 MHz): 300 W,
Ashing gas:
   NH₃ gas=700 mL/min (sccm), and
Ashing time: 100 sec.

For comparison, a sample was prepared such that neither etching nor ashing was performed thereon (reference; Sample No. 1), and another sample was prepared such that only etching was performed thereon (etching damage only; Sample No. 2).

Of the samples subjected to the O₂ ashing (Samples No. 3 to No. 5), Sample No. 3 was subjected to no process after the O₂ ashing, Sample No. 4 was subjected to a silylation process after the O₂ ashing, and Sample No. 5 was subjected to an Ar plasma process after the O₂ ashing and then to the silylation process.

Of the samples subjected to the NH₃ ashing (Samples No. 6 to No. 10), Sample No. 6 was subjected to no process after the NH₃ ashing, Sample No. 7 was subjected to the silylation process after the NH₃ ashing, Sample No. 8 was subjected to an in-situ baking process after the NH₃ ashing and then to the silylation process, Sample No. 9 was subjected to an H₂ plasma process after the NH₃ ashing and then to the silylation process, and Sample No. 10 was subjected to an Ar plasma process after the NH₃ ashing and then to the silylation process

The process conditions used at this time were set as follows.

Baking process:
In-chamber pressure: 1,333 Pa (10 Torr),
Atmosphere gas:
   Ar gas=2,000 mL/min (sccm),
Wafer table temperature: 200° C., and
Process time: 150 sec.

H₂ plasma process:
In-chamber pressure: 13.3 Pa (100 mTorr),
Upper side RF power (60 MHz): 300 W,
Lower side RF power (2 MHz): 0 W (without bias),
Plasma gas:
   H₂ gas=400 mL/min (sccm), and
Process time: 15 sec.

Ar plasma process:
In-chamber pressure: 13.3 Pa (100 mTorr),
Upper side RF power (60 MHz): 300 W,
Lower side RF power (2 MHz): 300 W (with bias),
Plasma gas:
   Ar gas=400 mL/min (sccm), and
Process time: 15 sec.

Silylation process:
Silylation agent: TMSDMA,
In-chamber pressure: 6,650 Pa (50 Torr),
Wafer table temperature: 150° C., and
Process time: 15 sec.

The samples thus prepared were measured in terms of the specific dielectric constant thereof (k-value) at room temperature and 200° C. Table 1 shows the conditions described above as well as the k-value and recovery rate.

As shown in Table 1, where the O₂ ashing was performed, the k-value was sufficiently recovered by performing only the silylation process thereafter (Sample No. 4). Where the NH₃ ashing was performed, the k-value was recovered only to a small extent even by performing the silylation process thereafter (Sample No. 7). Where the NH₃ ashing was performed, the recovery rate of the k-value was increased by performing the baking process or plasma process before the silylation process (Samples No. 8, No. 9, and No. 10). Where the O₂ ashing was performed, the recovery rate of the k-value was rather decreased by performing the plasma process before the silylation process (Sample No. 5).

The present invention is not limited to the embodiments described above, and it may be modified in various manners. For example, the recovering process is exemplified by the silylation process, but the recovering process may be performed by use of another recovery gas. The Si-containing Low-k film, which is processed as an etching target film in the present invention, may be an MSQ (methyl-hydrogen-SilsesQuioxane), which is porous or dense, formed by an SOD apparatus. Alternatively, for example, an SiOC-based film, which is an inorganic insulating film formed by CVD, may be used. This film can be prepared from a conventional SiO₂ film by introducing methyl groups (—CH₃) into Si—O bonds present on the film to mix Si—CH₃ bonds therewith. Black Diamond (Applied Materials Ltd.), Coral (Novellus Ltd.), and Aurora (ASM Ltd.) correspond to this type. Some of them are dense while others are porous (with a lot of pores).

In the embodiment described above, the ashing is performed by use of NH₃ gas, but, according to the present invention, the ashing may be performed by use of another NH₃-based gas, instead of NH₃ gas. Further, even if the ashing is performed by use of anther gas, the present invention can be applied to a case where an NH₃-based gas comes into contact with an etched portion after the Si-containing Low-k film is etched. For example, this corresponds to a case where a Low-k film is etched by use of an F-containing gas and then etched by use of an NH₃-based gas, i.e., it is processed in two steps.

In the embodiment described above, the present invention is applied to a semiconductor device manufacturing process using a single damascene method or dual damascene method to form a copper interconnection line, but this is not limiting. The present invention may be applied to any semiconductor device manufacturing process which includes a step of removing an etching mask on an etching target film.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

TABLE 1

| | | | | | | | | | | | Recovery |
|---|---|---|---|---|---|---|---|---|---|---|---|
| | | | | | | | | | | | rate of |
| Sample | | | Baking | Plasma | Silylation | Process | Thickness | k-value (Room | k-value | | k-value |
| No. | Etching | Ashing | process | process | process (Gas) | content | (nm) | temperature) | (200° C.) | Δk | (%) |
| 1 | — | — | — | — | — | Reference | 99.8 | 2.85 | 2.57 | 0.29 | — |
| 2 | ∘ | — | — | — | — | Etching damage | 81.9 | 3.35 | 2.77 | 0.58 | — |
| 3 | ∘ | O₂ | — | — | — | O₂ ashing | 67.9 | 4.37 | 3.4 | 0.97 | — |
| | | | | | | damage | | | | | |
| 4 | ∘ | O₂ | — | — | TMSDMA | O₂ ashing + Silylation | 67.5 | 3.52 | 2.99 | 0.53 | 56 |
| | | | | | | process | | | | | |
| 5 | ∘ | O₂ | — | Ar | TMSDMA | Ar plasma | 63.8 | 4.08 | 3.35 | 0.73 | 19 |
| | | | | | | process (with | | | | | |
| | | | | | | bias) | | | | | |
| 6 | ∘ | NH₃ | — | — | — | NH₃ ashing | 69.4 | 4.08 | 3.26 | 0.82 | — |
| | | | | | | damage | | | | | |
| 7 | ∘ | NH₃ | — | — | TMSDMA | NH₃ ashing + Silylation | 69.6 | 3.93 | 3.23 | 0.7 | 12 |
| | | | | | | process | | | | | |
| 8 | ∘ | NH₃ | ∘ | — | TMSDMA | In-situ baking | 67.8 | 3.85 | 3.17 | 0.68 | 19 |
| | | | | | | process | | | | | |
| | | | | | | (200° C.) | | | | | |
| 9 | ∘ | NH₃ | — | H₂ | TMSDMA | H₂ plasma | 65.3 | 3.7 | 3.14 | 0.56 | 31 |
| | | | | | | process | | | | | |
| | | | | | | (without bias) | | | | | |
| 10 | ∘ | NH₃ | — | Ar | TMSDMA | Ar plasma | 63.7 | 3.69 | 4.05 | −0.36 | 32 |
| | | | | | | process (with | | | | | |
| | | | | | | bias) | | | | | |

What is claimed is:

1. A semiconductor device manufacturing method comprising:
forming an etching mask having a predetermined circuit pattern on an Si-containing low dielectric constant film disposed as an etching target film on a semiconductor substrate;
performing etching on the Si-containing low dielectric constant film through the etching mask by use of an F-containing gas, thereby forming a groove or hole in the Si-containing low dielectric constant film;
performing ashing after said etching, thereby removing the etching mask;
bringing about a state where an etched portion of the Si-containing low dielectric constant film is exposed to NH₃ gas after said etching and before or in said removing the etching mask;
removing a by-product formed on the etched portion of the Si-containing low dielectric constant film due to exposure to the NH₃ gas; and
supplying a predetermined recovery gas after said removing a by-product, thereby recovering damage of the Si-containing low dielectric constant film caused before or in said removing the etching mask.

2. The method according to claim 1, wherein said removing the etching mask is performed by ashing by use of a gas containing NH₃ gas, which brings about the state where an etched portion of the Si-containing low dielectric constant film is exposed to NH₃ gas.

3. The method according to claim 1, wherein said removing a by-product is performed by a plasma process.

4. The method according to claim 3, wherein the plasma process is performed while turning Ar gas, H₂ gas, or He gas into plasma in a vacuum.

5. The method according to claim 3, wherein said removing a by-product and said removing the etching mask are performed within the same process chamber.

6. The method according to claim 3, wherein said removing a by-product, said removing the etching mask, and said recovering damage are performed within the same process chamber.

7. The method according to claim 3, wherein said etching, said removing a by-product, said removing the etching mask, and said recovering damage are performed by a process system of a cluster type that comprises a plurality of process chambers each configured to perform a process within a vacuum atmosphere, and a transfer mechanism configured to transfer a semiconductor substrate between the process chambers without breaking a vacuum.

8. The method according to claim 1, wherein said removing a by-product is performed by a heat process.

9. The method according to claim 8, wherein the heat process is performed at a temperature of 150 to 350° C.

10. The method according to claim 8, wherein said etching, said removing a by-product, said removing the etching mask, and said recovering damage are performed by a process system of a cluster type that comprises a plurality of process chambers each configured to perform a process within a vacuum atmosphere, and a transfer mechanism configured to transfer a semiconductor substrate between the process chambers without breaking a vacuum.

11. The method according to claim 1, wherein said removing a by-product is performed by cleaning by use of a cleaning liquid.

12. The method according to claim 1, wherein said recovering damage is performed by a silylation process by use of a silylation gas as the recovery gas.

13. The method according to claim 12, wherein the silylation process is performed by use of a compound including silazane bonds (Si—N) in molecules as the recovery gas.

14. The method according to claim 13, wherein the compound including silazane bonds in molecules is selected from TMDS (1,1,3,3-Tetramethyldisilazane), TMSDMA (Dimethylaminotrimethylsilane), DMSDMA (Dimethylsilyldimethylamine), TMSPyrole (1-Trimethylsilylpyrole), BSTFA (N,O-Bis(trimethylsilyl)trifluoroacetamide), and BDMADMS (Bis(dimethylamino)dimethylsilane).

15. A storage medium that stores a program for execution on a computer to control a manufacturing system, wherein the program, when executed, causes the computer to control the manufacturing system to conduct a semiconductor device manufacturing method comprising:
forming an etching mask having a predetermined circuit pattern on an Si-containing low dielectric constant film disposed as an etching target film on a semiconductor substrate;
performing etching on the Si-containing low dielectric constant film through the etching mask by use of an F-containing gas, thereby forming a groove or hole in the Si-containing low dielectric constant film;
performing ashing after said etching, thereby removing the etching mask;
bringing about a state where an etched portion of the Si-containing low dielectric constant film is exposed to NH₃ gas after said etching and before or in said removing the etching mask;
removing a by-product formed on the etched portion of the Si-containing low dielectric constant film due to exposure to the NH₃ gas; and
supplying a predetermined recovery gas after said removing a by-product, thereby recovering damage of the Si-containing low dielectric constant film caused before or in said removing the etching mask.
